(19) United States
(12) Patent Application Publication
(10) Pub. No.: US 2006/0001623 A1
(43) Pub. Date: Jan. 5, 2006

(54) ORGANIC ELECTROLUMINESCENT DISPLAY AND METHOD FOR DRIVING THE SAME

(76) Inventor: Chih-Feng Sung, Miaoli (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,607

(22) Filed: Sep. 16, 2005

Related U.S. Application Data
(63) Continuation-in-part of application No. 10/065,647, filed on Nov. 6, 2002.

(30) Foreign Application Priority Data
Apr. 17, 2002 (TW) 91107826

(51) Int. Cl. G09G 3/30

(52) U.S. Cl. 345/77

(57) ABSTRACT

An organic electroluminescent display including a plurality of red pixels, each of the red pixels includes a first driving thin film transistor and a red organic light emitting diode, wherein the first driving thin film transistor has a first width/length ratio (W/L)_{R}; a plurality of green pixels, each of the green pixels includes a second driving thin film transistor and a green organic light emitting diode, wherein the second driving thin film transistor has a second width/length ratio (W/L)_{G}; and a plurality of blue pixels, each of the blue pixels includes a third driving thin film transistor and a blue organic light emitting diode, wherein the third driving thin film transistor has a third width/length ratio (W/L)_{B}. In particular, the ratio of the third width/length ratio to the second width/length ratio ((W/L)_{B}/(W/L)_{G}) is from 1.1 to 5.3.

### CROSS-REFERENCE TO RELATED APPLICATION

This application is a continuation-in-part of a prior application Ser. No. 10/065,647, filed Nov. 6, 2002, which claims the priority benefit of Taiwan application serial no. 91107826, filed on Apr. 17, 2002. All disclosures are incorporated herewith by reference.

### BACKGROUND OF THE INVENTION

1. Field of Invention

The present invention relates to a display and a method for driving the same. More particularly, the present invention relates to an organic electroluminescent display and a method for driving the same.

2. Description of Related Art

Dynamic recording of documentary through film has a long history. With the invention of cathode ray tube (CTR) and broadcasting equipment, television has become an indispensable electronic device in almost every family. Due to rapid progress in the electronic industry, CRTs are also used as monitors for desktop computers. However, the CRT is now gradually being phased out due to radiation hazards and the bulkiness of the CRT body that needs to house an electron gun.

Because of radiation hazards and bulkiness, flat panel displays have been developed. The types of flat panel displays now include liquid crystal display (LCD), field emission display (FED), organic electroluminescent display and plasma display (PDP).

Organic electroluminescence display is a type of self-illuminating device arranged to form a matrix of organic light emitting diodes (OLED). Each organic light emitting diode is driven by a low DC current to produce light having a high luminance and contrast. The OLED also has a high operating efficiency and carries very little weight. Moreover, the OLED may emit light within a range of colors including the three primary colors red (R), green (G), blue (B) and white light. Consequently, OELD is currently the most actively developed type of flat panel display. Aside from high-resolution, lightweight, active illumination, quick response and energy saving capacity, advantages of the organic electroluminescent display further include a large viewing angle, good color contrast and low production cost. Currently, the OLED has many applications such as a light source at the back of a LCD or indicator panel in a mobile phone, a digital camera, a personal digital assistant (PDA) and so on.

According to the driving method, OLED may be classified into two major types, namely, a passive matrix driven type and an active matrix driven type. The passive matrix driven type OLED has a simpler structure and does not use any thin film transistor (TFT). Hence, the passive matrix driven OLED is easier and less expensive to produce. However, the passive matrix driven OLED has a lower resolution and consumes a lot of electrical energy if the display area is large. On the other hand, the active matrix driven organic electroluminescent display is suitable for fabricating large displays. The active matrix driven organic electroluminescence display has a wide viewing angle, illuminates brightly and responds quickly to control signals. Nevertheless, the active matrix driven organic electroluminescence display is slightly more expensive to produce.

According to the driving mode, flat panel displays can be categorized as voltage driven or current driven. The voltage driven mode is commonly employed in a thin film transistor liquid crystal display (TFT-LCD). To operate a voltage driven TFT-LCD, different voltages are fed to data lines so that different color gray scales are produced. The voltage driven TFT-LCD is relatively stable and cheap to manufacture. The organic electroluminescence display is a type of current driven display. To operate an organic electroluminescence display, different currents are fed to data lines so that different color gray scales are produced. Before operating this type of current driven pixel, however, new circuits and ICs must first be developed. The cost of developing new circuits and ICs is high. On the other hand, some technical problems are encountered if the voltage-driven circuit of a TFT-LCD is used to drive the organic electroluminescence display. Since the OLED characteristics for red (R), green (G) and blue (B) are different, different data voltages must be provided to produce a suitable R, G, B luminance ratio in the organic electroluminescence display for reproducing white light. Yet, the production of different output voltage data from a single IC is intrinsically difficult.

### SUMMARY OF THE INVENTION

Accordingly, one object of the present invention is to provide an organic electroluminescence display and a method for driving the same that employs the voltage-driven circuit of a thin film transistor liquid crystal display (TFT-LCD).

Another object of the present invention is to provide an organic electroluminescence display and a method for driving the same capable of producing white light and full coloration.

To achieve these and other advantages and in accordance with the purpose of the invention, as embodied and broadly described herein, the invention provides an organic electroluminescent display comprising a plurality of red pixels, each of the red pixels comprises a first driving thin film transistor and a red organic light emitting diode, wherein the first driving thin film transistor has a first width/length ratio (W/L)_{R}; a plurality of green pixels, each of the green pixels comprises a second driving thin film transistor and a green organic light emitting diode, wherein the second driving thin film transistor has a second width/length ratio (W/L)_{G}; and a plurality of blue pixels, each of the blue pixels comprises a third driving thin film transistor and a blue organic light emitting diode, wherein the third driving thin film transistor has a third width/length ratio (W/L)_{B}. In particular, the ratio of the third width/length ratio to the second width/length ratio ((W/L)_{B}/(W/L)_{G}) is from 1.1 to 5.3.

The present invention also provides a method for driving an organic electroluminescent display. First, an organic electroluminescent display as above mentioned is provided. Then, an identical data voltage for each of the red, green and blue pixels is provided, wherein a first driving current is generated by the first driving thin film transistor, a second driving current is generated by the second driving thin film transistor and a third driving current is generated by the third driving thin film transistor so that the luminance of red light emitted from the red organic light emitting diode, the luminance of green light emitted from the green organic light emitting diode and the luminance of blue light emitted from the blue light emitting diode are in such a ratio that white light is produced and full coloration is attained.

In brief, this invention uses the voltage-driven circuit of a conventional TFT-LCD such that the pixel is capable of outputting a different driving current to each OLED having a characteristic red, green or blue coloration under identical data voltage condition. Different driving currents are produced because of different channel width/length ratio of the TFT driver in each pixel. Consequently, an appropriate luminance ratio between red, green and blue lights may be set to reproduce white light through the red, green and blue OLED and hence attain full coloration.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram showing an equivalent driving circuit for a pixel inside a display device designed according to one preferred embodiment of this invention;

FIG. 2 is a graph showing the relationship between emission efficiency and luminance for red, green and blue OLED; and

FIG. 3 is a graph showing the relationship between luminance and driving current for red, green and blue OLED.

FIG. 4 is a diagram showing an organic electroluminescent display according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

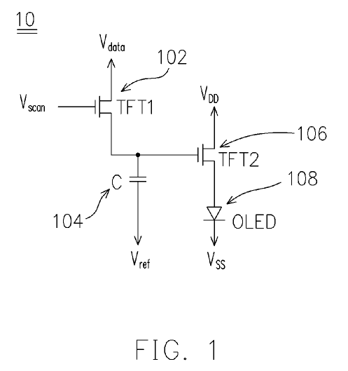

FIG. 1 is a diagram showing an equivalent driving circuit for a pixel inside a display device designed according to one preferred embodiment of this invention. As shown in FIG. 1, each pixel 10 includes a thin film transistor switch (TFT1) 102, a capacitor 104, a driving thin film transistor (TFT2) 106 and an organic light emitting diode (OLED) 108. The OLED 108 is an actively driven matrix.

The thin film transistor switch (TFT1) 102 has a drain terminal, a gate terminal and a source terminal. The capacitor (C) 104 has a first terminal and a second terminal. The driving thin film transistor (TFT2) 106 has a drain terminal, a gate terminal and a source terminal. The organic light emitting diode 108 has a positive electrode and a negative electrode. The drain terminal of thin film transistor switch (TFT1) 102 is coupled to a data voltage. The gate terminal of the thin film transistor switch (TFT1) 102 is coupled to a scanning voltage. The source terminal of the thin film transistor switch (TFT1) 102 is coupled to the first terminal of the capacitor (C) 104 and the gate terminal of the driving thin film transistor (TFT2) 106. The second terminal of the capacitor (C) 104 is coupled to a power supplier at a reference voltage V_{ref}. The drain terminal of the driving thin film transistor (TFT2) 106 is coupled to a power supplier at a voltage V_{DD}. The negative terminal of the organic light emitting diode (OLED) 108 is coupled to a power supplier at a voltage V_{SS}. In addition, the data voltage and the supply voltage (V_{DD}) are provided by a voltage source.

The following is a description of the operation of the pixel circuit. When the scanning voltage is at a high voltage level, voltage (V_{gs1}) between the gate terminal and the source terminal of the thin film transistor switch (TFT1) 102 is greater than a threshold voltage. Hence, the thin film transistor switch (TFT1) 102 conducts and the data voltage charges up the capacitor (C) 104. When the capacitor (C) 104 is charged up to a voltage equal to the voltage (V_{gs2}) between the gate terminal and source terminal of the driving thin film transistor (TFT2) 106, the driving thin film transistor (TFT2) 106 conducts. This leads to a driving current flowing between the drain terminal and the source terminal. The driving current flows through the organic light emitting diode (OLED) 108 to light up the device.

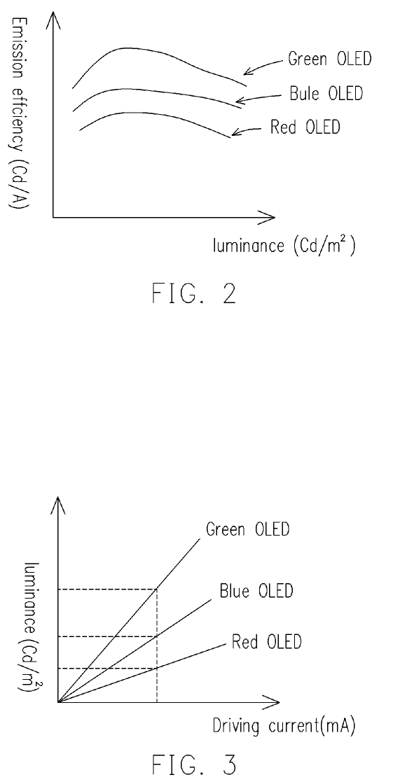

FIG. 2 is a graph showing the relationship between emission efficiency (EF) (units in candela/ampere, Cd/A) and luminance (units in candela/square meter, Cd/m²) for red (R), green (G) and blue (B) organic light emitting diode (OLED). As shown in FIG. 2, the emission efficiency and luminance for red OLED, green OLED and blue OLED are all different. Furthermore, luminance of the red, green and blue OLED may differ according to the structural layout and the material used. In general, luminance of an OLED is the product of the emission efficiency, the driving current passing through unit area of the OLED and a constant. FIG. 3 is a graph showing the relationship between luminance and driving current for red (R), green (G) and blue (B) OLED. As shown in FIG. 3, green OLED emits the highest luminance, blue OLED emits the second highest luminance and the red OLED emits the lowest luminance when subjected to an identical driving current.

Accordingly, red, green and blue OLED all have slightly different characteristic properties under an identical data voltage. Hence, driving current to red, green and blue OLED must be adjusted according to a selected luminance ratio before white light is produced. Drain current Id produced by a thin film transistor (TFT) at the saturation region follows a formula: I_{d}=(½)×μₙ×Cₒₓ×(W/L)×(V_{gs}−Vₜₕ)², where electron mobility μₙ and gate capacitance for unit area Cₒₓ has a constant value, Vₜₕ is threshold voltage of the thin film transistor (TFT), W is channel width of the thin film transistor (TFT) and L is the length of the thin film transistor (TFT). Since voltages between the gate terminal and source terminal of the driving thin film transistor for driving the red, green and blue OLED are identical (that is, V_{gsR}=V_{gsG}=V_{gsB}), the driving thin film transistor (TFT) can be set to produce different driving current for driving each type of color OLED by changing the width/length (W/L) ratio of the driving thin film transistor (TFT). Ultimately, red, green and blue OLED emit light having a suitable mix of luminance ratio to produce white light and hence attain full coloration.

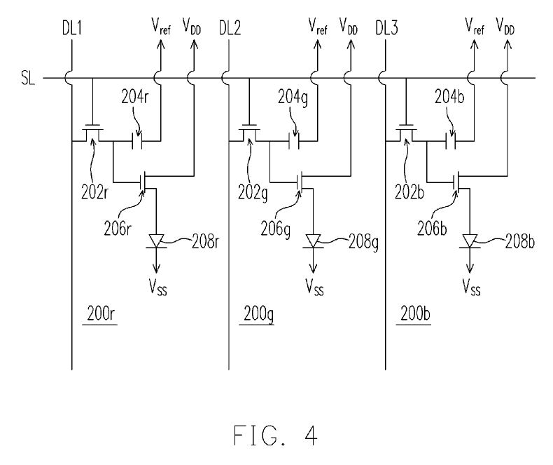

According to an embodiment of the present invention, an organic electroluminescent display is provided. As shown in FIG. 4, the organic electroluminescent display comprises a plurality of red pixels 200r, a plurality of green pixels 200g and a plurality of blue pixels 200b (the drawing only shows three pixels for illustration). Each of the red pixels 200r comprises a driving thin film transistor 206r and a red organic light emitting diode 208r. Each of the green pixels 200g comprises a driving thin film transistor 206g and a green organic light emitting diode 208g. Each of the blue pixels 200b comprises a driving thin film transistor 206b and a blue organic light emitting diode 208b. In particular, the driving thin film transistor 206r has a width/length ratio (W/L)_{R}, the driving thin film transistor 206g has a width/length ratio (W/L)_{G}, and the driving thin film transistor 206b has a width/length ratio (W/L)_{B}, wherein the ratio ((W/L)_{B}/(W/L)_{G}) is from 1.1 to 5.3.

In an embodiment, the red pixel 200r further comprises a switch thin film transistor 202r and a capacitor 204r. The green pixel 200g further comprises a switch thin film transistor 202g and a capacitor 204g. The blue pixel 200b further comprises a switch thin film transistor 202b and a capacitor 204b. The switch thin film transistors 202r, 202g, 202b are electrically connected to the scan line SL and the data lines DL1˜DL3. In the red pixel 200r, the switch thin film transistor 202r is electrically connected to the capacitors 204r and the driving thin film transistor 206r, and the driving thin film transistor 206r is electrically connected to the red organic light emitting diode 208r. In the green pixel 200g, the switch thin film transistor 202g is electrically connected to the capacitor 204g and the driving thin film transistor 206g, and the driving thin film transistor 206g is electrically connected to the red organic light emitting diode 208g. In the blue pixel 200b, the switch thin film transistor 202b is electrically connected to the capacitor 204b and the driving thin film transistor 206b, and the driving thin film transistor 206b is electrically connected to the red organic light emitting diode 208b. In addition, one terminal of the respective capacitors 204r, 204g, 204b is electrically connected to the driving thin film transistors 206r, 206g, 206b, and the other terminal of the respective capacitors 204r, 204g, 204b is coupled to a power supply at a voltage level (V_{ref}). Moreover, the driving thin film transistors 206r, 206g, 206b are electrically connected to a power supply at a voltage level (V_{DD}). The red, green and blue organic light emitting diodes 208r, 208g, 208b are electrically connected to a power supply at a voltage level (V_{SS}).

In order to realize the full-color display and white light production, red, green and blue pixels 200r, 200g, 200b with high color purity are indispensable. For this reason, in the area of the organic electroluminescent display as well, considerable research and development have been made regarding luminescent materials and elements having a chromaticity based on NTSC (National Television System Committee) standard. Color may be measured using CIE (x,y) coordinates, which are well known to the art. White light having CIE (0.34, 0.34) based on NTSC is high pure white light. Currently the green organic light emitting diode has stable luminance or emitting efficiency but the blue organic light emitting diode has unstable luminance or emitting efficiency because of its luminescent material. Hence, according to an embodiment of the present invention, the driving thin film transistors of the pixels in the organic electroluminescent display has a characteristic of that the ratio (W/L)_{B}/(W/L)_{G} is from 1.1 to 5.3 that can produce white light having CIE (0.34, 0.34). For example, the luminance ratio of red pixel: green pixel: blue pixel is 7:16:2˜10. The red pixel has CIE (0.65, 0.34) and the green pixel has CIE (0.31, 0.62). But, CIE (y) for the blue pixel is varied from 0.08 to 0.19. The W/L of the driving thin film transistors in red, green and blue pixels can be set as Example 1˜4 listed in Table 1 that satisfying (W/L)_{B}/(W/L)_{G}=1.1˜5.3 for producing white light having CIE (0.34, 0.34).

TABLE 1

| | Blue pixel | Blue pixel | | | |
|---|---|---|---|---|---|
| | Luminance (cd/A) | CIE (y) | (W/L)_{R} | (W/L)_{G} | (W/L)_{B} |
| Example 1 | 2 | 0.19 | 1.6 | 1.0 | 5.3 |
| Example 2 | 2 | 0.08 | 0.9 | 1.0 | 1.2 |
| Example 3 | 5 | 0.19 | 1.6 | 1.2 | 1.0 |
| Example 4 | 10 | 0.19 | 1.6 | 1.0 | 1.1 |

The method for driving the organic electroluminescent display of FIG. 4 first providing an identical data voltage for each of the red, green and blue pixels. In the meanwhile, a first driving current is generated by the driving thin film transistor 206r, a second driving current is generated by the driving thin film transistor 206g and a third driving current is generated by the driving thin film transistor 206b so that the luminance of red light emitted from the red organic light emitting diode 208r, the luminance of green light emitted from the green organic light emitting diode 208g and the luminance of blue light emitted from the blue light emitting diode 208b are in such a ratio that white light is produced and full coloration is attained.

In summary, this invention uses the voltage-driven circuit of a conventional TFT-LCD such that the pixel is capable of outputting a different driving current to each OLED having a characteristic red, green or blue coloration under identical data voltage conditions. Different driving currents are produced because of different channel width/length ratio of the driving TFT in each pixel. Consequently, an appropriate luminance ratio between red, green and blue lights may be set to reproduce white light through the red, green and blue OLED and hence attain full coloration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic electroluminescent display, comprising:
a plurality of red pixels, wherein each of the red pixels comprises a first driving thin film transistor and a red organic light emitting diode, and the first driving thin film transistor has a first width/length ratio (W/L)_{R};
a plurality of green pixels, wherein each of the green pixels comprises a second driving thin film transistor and a green organic light emitting diode, and the second driving thin film transistor has a second width/length ratio (W/L)_{G}; and
a plurality of blue pixels, wherein each of the blue pixels comprises a third driving thin film transistor and a blue organic light emitting diode, and the third driving thin film transistor has a third width/length ratio (W/L)_{B},
wherein the ratio of the third width/length ratio to the second width/length ratio ((W/L)_{B}/(W/L)_{G}) is from about 1.1 to 5.3.

2. The organic electroluminescent display of claim 1, wherein the luminance ratio of red pixel:green pixel:blue pixel is about 7:16:2˜10.

3. The organic electroluminescent display of claim 1, wherein white light mixed from the red, green and blue pixels has CIE coordinate about (0.33, 0.33).

4. The organic electroluminescent display of claim 1, wherein each of the red, green and blue pixels further includes a switch thin film transistor and a capacitor.

5. The organic electroluminescent display of claim 1, wherein the first, second and third driving thin film transistors are electrically connected to a power supply at a first voltage level.

6. The organic electroluminescent display of claim 1, wherein the red, green and blue organic light emitting diodes are electrically connected to a power supply at a second voltage level.

7. A method for driving an organic electroluminescent display, comprising:
providing an organic electroluminescent display of claim 1; and
providing an identical data voltage for each of the red, green and blue pixels;
wherein a first driving current is generated by the first driving thin film transistor, a second driving current is generated by the second driving thin film transistor and a third driving current is generated by the third driving thin film transistor so that the luminance of red light emitted from the red organic light emitting diode, the luminance of green light emitted from the green organic light emitting diode and the luminance of blue light emitted from the blue light emitting diode are in such a ratio that white light is produced and full coloration is attained.

8. The method of claim 7, wherein the luminance ratio of red pixel:green pixel:blue pixel is about 7:16:2˜10.

9. The method of claim 7, wherein white light mixed from the red, green and blue pixels has CIE coordinate about (0.33, 0.33).

10. The method of claim 7, wherein the luminance of red light emitted by the red organic light emitting diode depends on the structure and material forming the red organic light emitting diode.

11. The method of claim 7, wherein the luminance of green light emitted by the green organic light emitting diode depends on the structure and material forming the green organic light emitting diode.

12. The method of claim 7, wherein the luminance of blue light emitted by the blue organic light emitting diode depends on the structure and material forming the blue organic light emitting diode.

13. The method of claim 7, wherein the luminance efficiency of red light is proportional to the first driving current.

14. The method of claim 7, wherein the luminance efficiency of green light is proportional to the second driving current.

15. The method of claim 7, wherein the luminance efficiency of blue light is proportional to the third driving current.

16. The method of claim 7, wherein the first, second and third driving thin film transistors are electrically connected to a power supply at a first voltage level.

17. The method of claim 7, wherein the red, green and blue organic light emitting diodes are electrically connected to a power supply at a second voltage level.

18. The method of claim 7, wherein each of the red, green and blue pixels further includes further includes a switch thin film transistor and a capacitor.
